(19) United States
(12) Patent Application Publication
(10) Pub. No.: US 2024/0076778 A1
(43) Pub. Date: Mar. 7, 2024

(54) SYSTEM AND APPARATUS FOR A REACTION CHAMBER

(71) Applicant: ASM IP Holding B.V., Almere (NL)

(72) Inventors: Jessica Akemi Cimada da Silva, Chandler, AZ (US); Michael Schmotzer, Chandler, AZ (US)

(21) Appl. No.: 18/239,176

(22) Filed: Aug. 29, 2023

Related U.S. Application Data
(60) Provisional application No. 63/403,232, filed on Sep. 1, 2022.

(51) Int. Cl. C23C 16/458; C23C 16/455

(52) U.S. Cl. CPC C23C 16/4585; C23C 16/45565; C23C 16/45591

(57) ABSTRACT

Various embodiments of the present technology may provide a system and apparatus for reaction chamber. The system and apparatus may contain a reaction chamber having a spacer plate disposed between a lower chamber of the reaction chamber and a showerhead. An active heating element may be embedded within the spacer plate. A flow control ring, disposed adjacent to the spacer plate, is heated by conduction from the spacer plate heating element.

### CROSS-REFERENCE TO RELATED APPLICATIONS

This application is a nonprovisional of, and claims priority to and the benefit of, U.S. Provisional Patent Application No. 63/403,232, filed Sep. 1, 2022 and entitled “SYSTEM AND APPARATUS FOR A REACTION CHAMBER,” which is hereby incorporated by reference herein.

### TECHNICAL FIELD

The present disclosure generally relates to reactor systems used, for example, in the manufacture of semiconductor wafers. More particularly, the disclosure relates to a system and apparatus to provide improved temperature profiles on a susceptor by providing active heating on various components surrounding the susceptor.

### BACKGROUND OF THE TECHNOLOGY

During the semiconductor manufacturing process, heat loss at the edge of the susceptor and/or wafer may occur. Uneven temperature profiles on the susceptor and/or wafer may result in deposition non-uniformity and/or poor electrical characteristics of the wafer.

### SUMMARY OF THE INVENTION

Various embodiments of the present technology may provide a system and apparatus for reaction chamber. The system and apparatus may contain a reaction chamber having a spacer plate disposed between a lower chamber of the reaction chamber and a showerhead. An active heating element may be embedded within the spacer plate. A flow control ring, disposed adjacent to the spacer plate, is heated by conduction from the spacer plate heating element.

In one embodiment, a reaction chamber, comprises an interior space defined by a sidewall, a bottom panel coupled to the sidewall, and a showerhead arranged opposite the bottom panel and coupled to the sidewall, wherein the sidewall comprises an interior-facing surface that forms a circular shape having a first circumference; a spacer plate integrated in the sidewall and comprising a heating element, and comprising a lip that extends outwards from the sidewall and into the interior space, and extends along the entire first circumference of the interior-facing surface of the sidewall; and a flow control ring positioned in direct contact with the spacer plate, wherein the flow control ring extends along an entire outer edge of the spacer plate.

In another embodiment, a reaction chamber, comprises an interior space defined by a sidewall, a bottom panel coupled to the sidewall, and a showerhead arranged opposite the bottom panel and coupled to the sidewall, wherein sidewall comprises an interior-facing surface that forms a circular shape having a first circumference; a spacer plate extending from the interior-facing surface of the sidewall into the interior space and having a second circumference; a heating element embedded within the spacer plate; and a flow control ring positioned in direct contact with the spacer plate, wherein the flow control ring extends along an entire outer edge of the spacer plate and has a third circumference that is less than the second circumference.

In yet another embodiment, a system, comprises: a reaction chamber comprising an interior space defined by: a sidewall comprising an interior-facing surface that forms a circular shape having a first circumference; a bottom panel coupled to the sidewall; and a showerhead arranged opposite the bottom panel and coupled to the sidewall; a spacer plate extending from the interior-facing surface of the sidewall into the interior space, wherein the spacer plate extends along the entire first circumference of the interior-facing surface of the sidewall; a heating element embedded within the spacer plate; a flow control ring positioned in direct contact with the spacer plate, wherein the flow control ring extends from an outer edge of the spacer plate into the interior space and has a second circumference; a susceptor disposed in the interior space and adjacent to the flow control ring, the susceptor comprising a top surface; and a cap disposed on and entirely covering the top surface of the susceptor, wherein the cap is adjacent to and spaced apart from the flow control ring.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with an exemplary embodiment of the present technology;

FIG. 2 representatively illustrates a system in accordance with an exemplary embodiment of the present technology;

FIG. 3 representatively illustrates a top view of a portion of the system in accordance with an exemplary embodiment of the present technology;

FIG. 4 representatively illustrates a top view of a portion of the system in accordance with an exemplary embodiment of the present technology;

FIG. 5 representatively illustrates a top view of a portion of the system in accordance with an exemplary embodiment of the present technology;

FIG. 6 representatively illustrates a top view of a portion of the system in accordance with an exemplary embodiment of the present technology;

FIG. 7 representatively illustrates readout of pixel data in accordance with an exemplary embodiment of the present technology;

FIG. 8 representatively illustrates a top view of a portion of the system in accordance with an exemplary embodiment of the present technology;

FIG. 9 representatively illustrates a cross-sectional view of a portion of the system in accordance with an exemplary embodiment of the present technology;

FIG. 10 representatively illustrates a cross-sectional view of a portion of the system in accordance with an exemplary embodiment of the present technology;

FIG. 11 representatively illustrates a cross-sectional view of a portion of the system in accordance with an exemplary embodiment of the present technology; and

FIG. 12 representatively illustrates a cross-sectional view of a portion of the system in accordance with an exemplary embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various susceptors, susceptor caps, flow control rings, showerheads, and heating elements. Further, the present technology may employ any number of conventional techniques for delivering precursor to the reaction chamber, removing precursor from the reaction chamber, heating the susceptor, and the like.

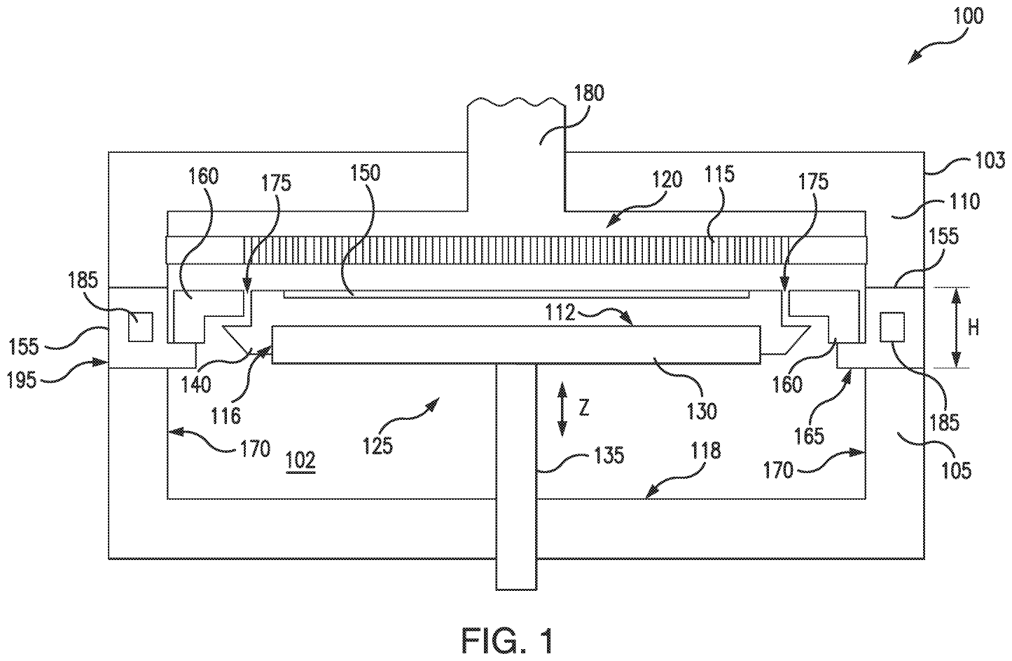

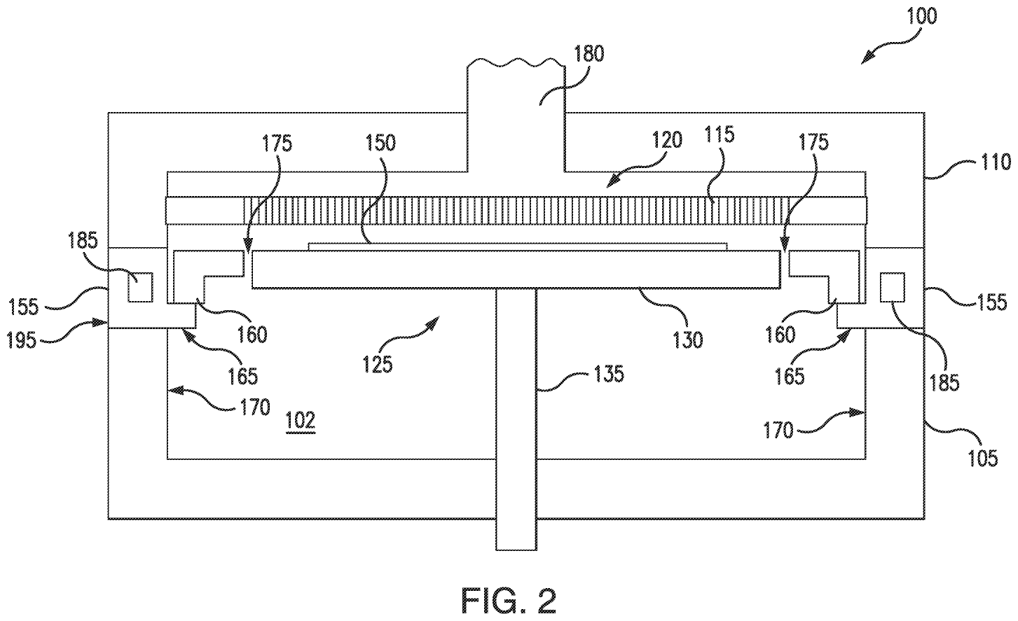

Referring to FIGS. 1 and 2, an exemplary system 100 may comprise a reaction chamber 103 for processing a substrate, such as a wafer 150. The reaction chamber 103 may comprise an interior space 102 defined by a vertically-oriented sidewall 105 having an interior-facing surface 170 (which defines a perimeter of the interior space), a horizontally-oriented bottom surface 118, and a showerhead 110. In an exemplary embodiment, the interior-facing surface 170 may have a circular shape having a first circumference. The system 100 may further comprise an inlet 180 to deliver various precursors to the reaction chamber 103.

The showerhead 110 may comprise a fixture 115 comprising a plurality of through-holes 120 configured to flow precursor from the inlet 180 toward the wafer 150. The showerhead 110 may be positioned adjacent to and supported by the sidewall 105. In various embodiments, the showerhead 110 may be separated from the sidewalls 105.

The system 100 may further comprise a susceptor 125 disposed within the interior space 102 of the reaction chamber 103 and configured to support the wafer 150. The susceptor 125 may comprise a plate 130 supported by a pedestal 135. In various embodiments, the susceptor 125 may be configured to move up and down along a z-axis (Z). FIGS. 1 and 2 illustrate the susceptor 125 in an up-most position. In various embodiments, the plate 130 may be formed from ceramic (alumina, AlOx), or a metal (e.g., stainless steel, Hastelloy, or the like). The plate 130 may comprise a top surface 130 that is horizontally-oriented and positioned directly below the fixture 115.

In various embodiments, the system 100 may further comprise a susceptor cap 140 disposed on the top surface 112 of the plate 130. The susceptor cap 140 may completely cover the top surface 112 of the plate 130. Further, the susceptor cap 140 may extend down and around a perimeter edge 116 of the plate 130. Further, the susceptor cap 140 may extend away from the perimeter edge 116 and toward the sidewall 105 of the reaction chamber 103. In various embodiments, the susceptor cap 140 may comprise a recessed area to receive the wafer 150. In various embodiments, the susceptor cap 140 may be formed from a metal, such as titanium or any other suitable metals, or other suitable materials, such as quartz.

In various embodiments, the reaction chamber 103 may further comprise a spacer plate 155 integrated within the sidewall 105. The spacer plate 155 may be defined by a region of the sidewall that meets the showerhead 110 and may have a height H that is based on the dimensions (e.g., height) of the plate 130 and/or the susceptor cap 140. In various embodiments, the spacer plate 155 may further comprise a lip 165 that extends away from the interior-facing surface 140 and into the interior space 102. The lip 165 may extend around the entire perimeter of the interior space 102.

In various embodiments, the reaction chamber 103 may further comprise a flow control ring 160 adjacent to the spacer plate 155. In some embodiments, the flow control ring 160 may rest on the lip 165 of the spacer plate 155, such that the flow control ring may move relative to the spacer plate 155. In other words, the flow control ring 160 is not fixed or bonded to the spacer plate 155. However, in other embodiments, the flow control ring 160 may be fixed or bonded to the spacer plate 155, such that the flow control ring 160 does not move relative to the spacer plate 155.

In various embodiments, and in cases where a susceptor cap is used, the flow control ring 160 may be adjacent to the susceptor cap 140 (when the susceptor 125 is in the up-most position). In addition, the flow control ring 160 may be separated from the susceptor cap 140 by a gap 175. The gap 175 may be formed by an edge of the flow control ring 160 and an edge of the susceptor cap 140. As illustrated, the edges of the flow control ring 160 and the susceptor cap 140 are vertically-oriented, however, the edges could be angled or be a combination of angled, vertical, and/or horizontal sections. The gap 175 may range from 0 mm to 1 mm. For example, the gap 175 may be approximately 0.5 mm.

In various embodiments, and in cases where a susceptor cap is not used, the flow control ring 160 may be adjacent to the plate 130 of the susceptor 125 (when the susceptor 125 is in the up-most position). In addition, the flow control ring 160 may be separated from the plate 130 by the gap 175. In the present case, the gap 175 may be formed by an edge of the flow control ring 160 and an edge of the plate 130 of the susceptor 125. As illustrated, the edges of the flow control ring 160 and the susceptor cap 140 are vertically-oriented, however, the edges could be angled or be a combination of angled, vertical, and/or horizontal sections. The gap 175 may range from 0 mm to 1 mm. For example, the gap 175 may be approximately 0.5 mm.

In various embodiments, the system 100 may further comprise a heating element 185 to provide active heating to one or more components and indirect heating to other components. In an exemplary embodiment, the heating element 185 may be disposed in the spacer plate 155 or on the spacer plate 155. For example, in some embodiments, the heating element 185 may be embedded (i.e., surrounded) within the spacer plate 155 and/or the sidewall 105. Additionally, or alternatively, the heating element 185 may be attached to an outer surface 195 of the spacer plate 155 portion of the sidewall 105. In various embodiments, the heating element 185 may be in the form of a wire, cartridge, or other suitable shape/form. In various embodiments, the heating element 185 may comprise a resistive heating element formed of a metal material, or any other suitable heating element type.

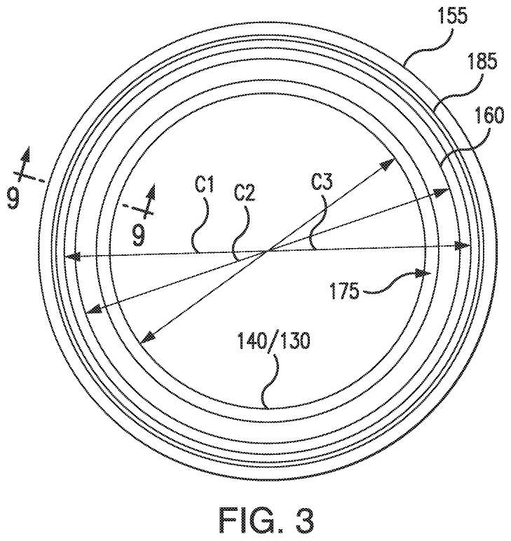

Referring to FIG. 3, in various embodiments, the spacer plate 155 may have a first circumference C1, the flow control ring 160 may have a second circumference C2, and the susceptor 140 or susceptor cap 130 may have a third circumference C3. The second circumference C2 may be less than the first circumference C1 and greater than the third circumference C3. The first circumference C3 may be greater than the second and third circumferences C2, C3. In other words, C1>C2>C3.

In an exemplary embodiment, the heating element 185 may comprise a single wire extending along the entire first circumference of the spacer plate 155. In the present case, the heating element 185 may have a circular pattern with a circumference that is larger than the first circumference C1. Alternatively, and referring to FIG. 7, the heating element 185 may have a serpentine pattern, a zig-zag pattern, or any other suitable patterns.

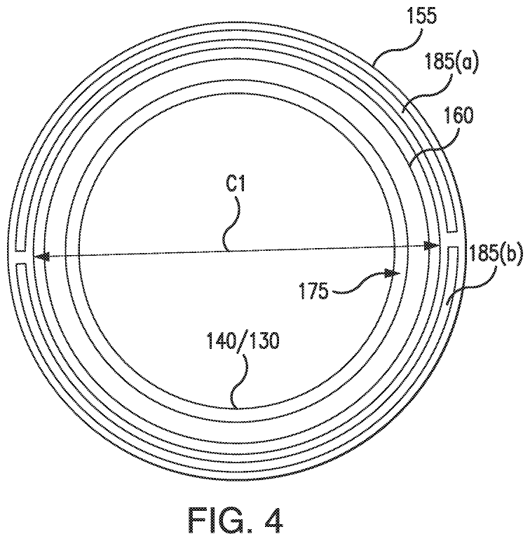

In various embodiments, and referring to FIG. 4, the heating element 185 may comprise a plurality of heating elements extending along the entire first circumference of the spacer plate 155. For example, the heating element 185 may comprise a first heating element 185(a) and a second heating element 185(b). In the present embodiment, the first heating element 185(a) may form a semi-circle shape along half of the spacer plate 155 while the second heating element 185(b) may form a semi-circle along the remaining half of the spacer plate 155. In some embodiments, the first heating element 185(a) may be independently controlled relative to the second heating element 185(b). For example, the first heating element 185(a) may be set to a first temperature while the second heating element 185(b) is set to a second temperature that is different from the first temperature. Alternatively, the first and second heating elements 185(a), 185(b) may be controlled simultaneously, such that they are both set to the same temperature.

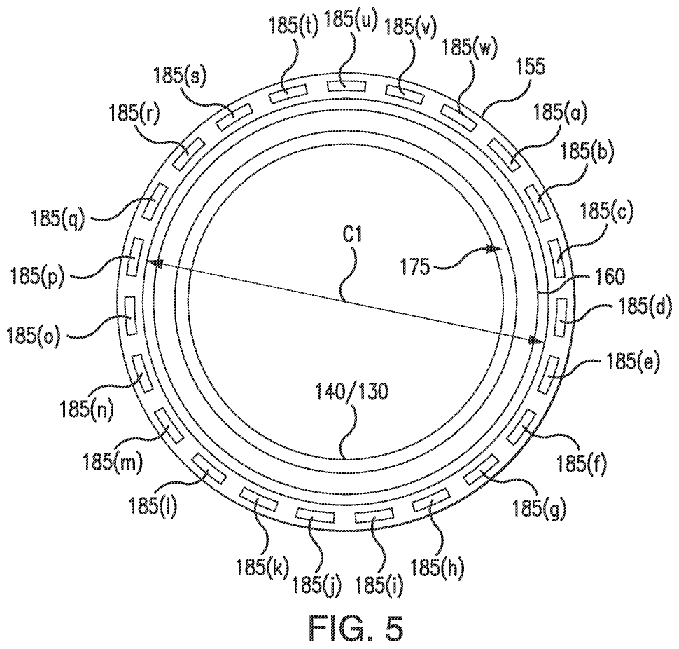

In various embodiments, and referring to FIG. 5, the heating element 185 may comprise more than two heating elements, such as heating elements 185(a)-185(w). In the present embodiment, the plurality of heating elements 185(a)-185(w) are disposed within the spacer plate 155 and may be positioned equidistant from each other. In some embodiments, the plurality of heating elements 185(a)-185(w) may be independently controlled. For example, the first heating element 185(a) may be set to a first temperature while the second heating element 185(b) is set to a second temperature that is different from the first temperature. Alternatively, the plurality of heating elements 185(a)-185(w) may be controlled simultaneously, such that they are all set to the same temperature. In the present embodiment, the heating elements 185(a)-185(w) may be a cartridge style heating element.

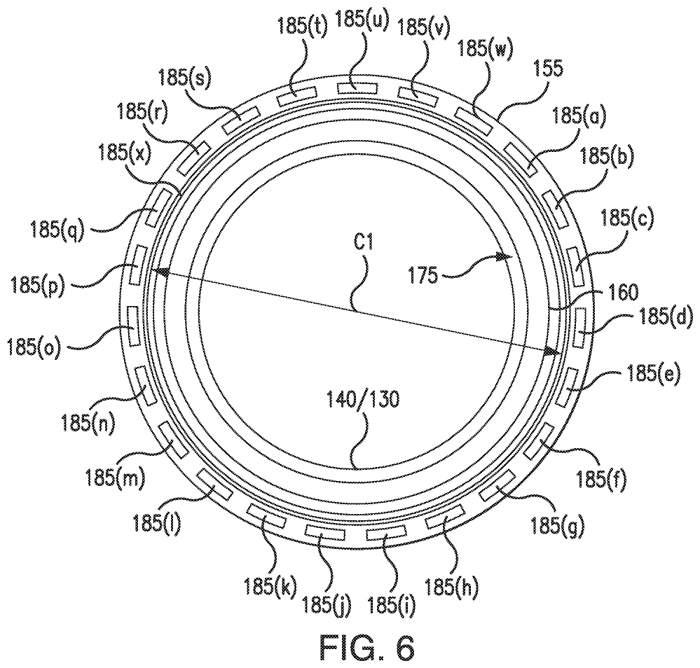

In various embodiments, and referring to FIG. 6, the heating element 185 may comprise more than two heating elements, such as heating elements 185(a)-185(x). In the present embodiment, the plurality of heating elements 185(a)-185(x) are disposed within the spacer plate 155. Heating elements 185(a)-185(w) and may be positioned along the first circumference C1 (FIG. 3) and equidistant from each other. One heating element from the plurality of heating elements, such as heating element 185(x), may be positioned along the first circumference C1 and adjacent to the remaining heating elements (e.g., heating elements 185(a)-185(w). In some embodiments, the plurality of heating elements 185(a)-185(x) may be independently controlled. For example, one heating element (e.g., heating element 185(x), may be set to a first temperature while at least one of the remaining heating elements may be set a second temperature that is different from the first temperature. In addition, within the set of remaining heating elements (e.g., 185(a)-185(w)), each of those heating elements may be independently controlled. For example, the first heating element 185(a) may be set to a first temperature while the second heating element 185(b) is set to a second temperature that is different from the first temperature. Alternatively, the plurality of heating elements 185(a)-185(w) may be controlled simultaneously, such that they are all set to the same temperature. In the present embodiment, the heating elements 185(a)-185(w) may be a cartridge style heating element, while heating element 185(x) may be a wire style heating element.

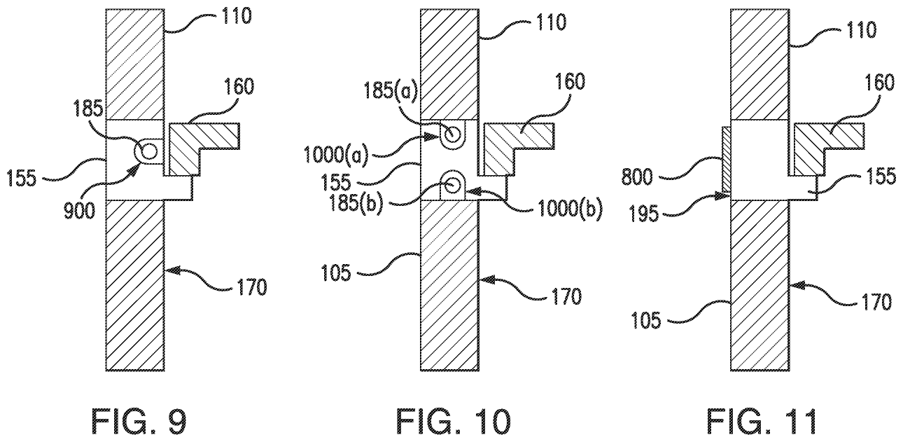

In various embodiments, and referring to FIGS. 9 and 10, the heating element 185 may be disposed in a channel formed in the spacer plate 155. In one embodiment, and referring to FIG. 9, a channel 900 may be formed within the interior-facing surface 170 of the spacer plate 155.

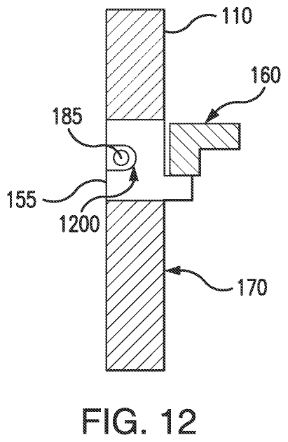

Additionally, or alternatively, and referring to FIG. 12, the heating element 185 may be disposed in a channel 1200 formed on the outer surface 195 of the spacer plate 155. The present channel 1200 may be used in conjunction with other channels, such as the channel 900 (FIG. 9) and/or channels 1000 (described below).

Additionally, or alternatively, and referring to FIG. 10, in a case comprising multiple heating elements, the system 100 may comprise a plurality of channels, such as channels 1000(a) and 1000(b). In the present embodiment, each channel 1000(a), 1000(b) is used to contain a respective heating element, such as heating elements 185(a) and 185(b).

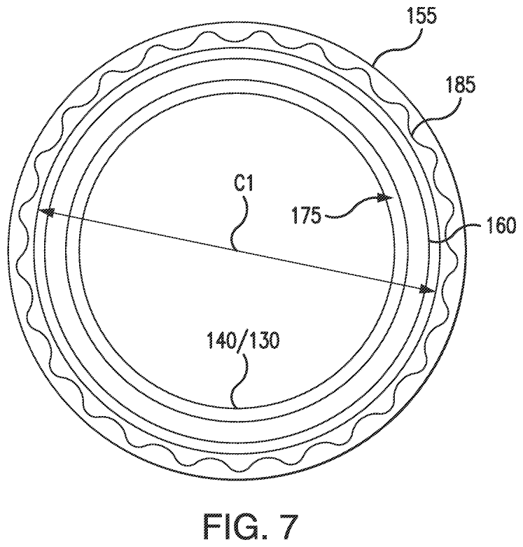

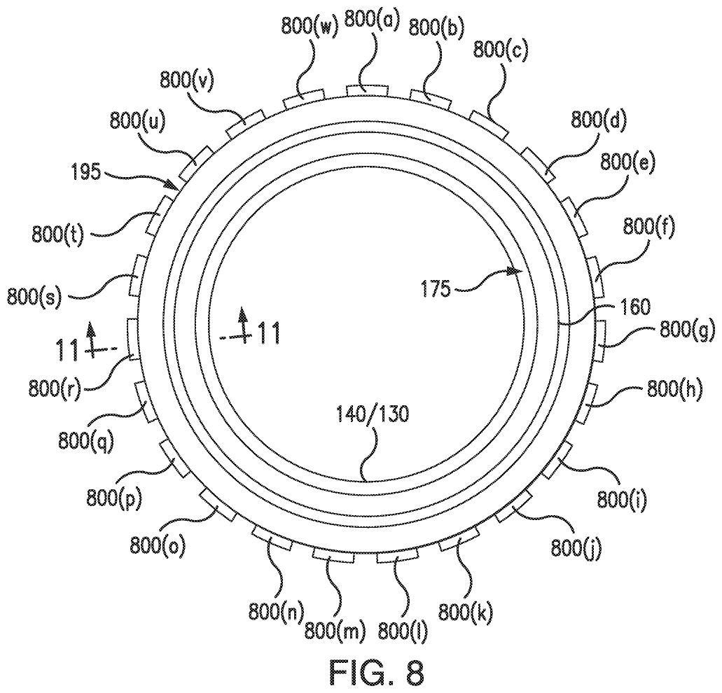

In various embodiments, and referring to FIGS. 8 and 11, the system 100 may comprise a plurality of exterior heating elements, such as heating elements 800(a)-800(w). The plurality of exterior heating elements 800(a)-800(w) may be directly fixed or adhered to the outer surface 195 of the spacer plate 155. In various embodiments, the plurality of exterior heating elements 800(a)-800(w) may be used in conjunction with any of the heating elements 185 described above or may be used alone.

In various embodiments, the system 100 may comprise one or more temperature sensors (not shown), (e.g., a thermocouple), to monitor the temperature of various structures, such as the plate 130 of the susceptor 125 and/or the spacer plate 155. In various embodiments, the temperature sensor may be embedded within the plate 130 of the susceptor 125 and/or the spacer plate 155. In various embodiments, the temperature sensor may comprise a plurality of temperature sensors disposed near or adjacent to a particular heating element to monitor the temperature in the location of the particular heating element. Signals and/or temperature data generated by the temperature sensor may be used to control the one or more heating elements 185 or external heating element 800.

In various embodiments, the system 100 may further comprise a controller (not shown) in communication with the temperature sensors and/or the heating elements 185. The controller may be configured to receive temperature data from the temperature sensors and control the heating elements according to the temperature data. For example, the controller may increase or decrease the temperature of one or more heating elements based on the temperature data and a desired temperature for that one or more heating element.

It will be understood by those of ordinary skill in the art that the system 100 may further comprise various electrical connections (not shown) and a power supply (not shown) to power the heating elements 185.

In operation, the one or more heating elements 185 are heated to a desired temperature, resulting in an overall heating of the spacer plate 155 including the lip 165. Since the flow control ring 160 is in physical contact with the spacer plate 155, the flow control ring 160 is heated by the heating element 185 via conduction heating. Heat from the flow control ring 160 is then transferred to the susceptor cap 140 or plate 130 via convection heating (by way of the gap 175). Heating of the susceptor cap 140 or plate 130 via the flow control ring 160 and spacer plate 155 may provide improved temperature control across the susceptor cap 140 or plate 130, and therefore improve thermal losses at the edge of the wafer 150. This thermal control and combination of thermal sources may improve deposition uniformity across the wafer 150 resulting in improved electrical characteristics of the wafer 150.

In an exemplary operation, the signals and/or temperature data from the temperature sensors may be transmitted to the controller (not shown). The controller may be configured to utilize the temperature data to dynamically control one or more heating elements. For example, a temperature sensor located at a 12 o'clock position may transmit a first signal to the controller that indicates that the temperature at the 12 o'clock position is X ° C. A temperature sensor located at a 6 o'clock position may transmit a second signal to the controller (either in sequence or simultaneously) that indicates that the temperature at the 6 o'clock position is Y ° C. (where XY). If it is desired to have a uniform temperature at the 12 o'clock and 6 o'clock positions, the controller may then operate to increase one or more heating elements that are neighboring/adjacent to the temperature sensor that indicated the lower temperature. In various embodiments, the controller may receive any number of signals from any number of temperature sensors placed at various locations. In addition, the controller may receive temperature data/signals from any number of temperature sensors and utilize the multiple temperature data/signal to increase or decrease the temperature of any number of heating elements to achieve a desired thermal profile. As discussed above, in various embodiments, each heating element may be individually controlled such that the temperature of one heating element may be increased while the temperature of a directly neighboring heating element may either stay the same, increase, or decrease based on a desired thermal profile.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. A reaction chamber, comprising:
an interior space defined by a sidewall, a bottom panel coupled to the sidewall, and a showerhead arranged opposite the bottom panel and coupled to the sidewall, wherein the sidewall comprises an interior-facing surface that forms a circular shape having a first circumference;
a spacer plate integrated in the sidewall and comprising a heating element, and comprising a lip that extends outwards from the sidewall and into the interior space, and extends along the entire first circumference of the interior-facing surface of the sidewall; and
a flow control ring positioned in direct contact with the spacer plate, wherein the flow control ring extends along an entire outer edge of the spacer plate.

2. The reaction chamber according to claim 1, wherein the heating element is embedded within the spacer plate.

3. The reaction chamber according to claim 1, wherein the flow control ring extends outwards from the spacer plate and into the interior space.

4. The reaction chamber according to claim 3, wherein the flow control ring has a circumference that is less than the circumference of the spacer plate.

5. The reaction chamber according to claim 1, wherein the flow control ring is in direct contact with the spacer.

6. The reaction chamber according to claim 1, wherein the heating element comprises a resistive heating element.

7. The reaction chamber according to claim 1, wherein the heating element is a single element that extends along the entire circumference of the spacer plate.

8. The reaction chamber according to claim 1, wherein the heating element comprises a plurality of heating elements, wherein the heating elements are spaced equidistant from each other.

9. The reaction chamber according to claim 8, wherein each heating element is configured to be independently controlled relative to the other heating elements.

10. A reaction chamber, comprising:
an interior space defined by a sidewall, a bottom panel coupled to the sidewall, and a showerhead arranged opposite the bottom panel and coupled to the sidewall, wherein sidewall comprises an interior-facing surface that forms a circular shape having a first circumference;
a spacer plate extending from the interior-facing surface of the sidewall into the interior space and having a second circumference;
a heating element embedded within the spacer plate; and
a flow control ring positioned in direct contact with the spacer plate, wherein the flow control ring extends along an entire outer edge of the spacer plate and has a third circumference that is less than the second circumference.

11. The reaction chamber according to claim 10, wherein the heating element is a single element that extends along the entire circumference of the spacer plate.

12. The reaction chamber according to claim 10, wherein the heating element comprises a plurality of heating elements, wherein the heating elements are spaced equidistant from each other.

13. The reaction chamber according to claim 12, wherein each heating element is configured to be independently controlled relative to the other heating elements.

14. The reaction chamber according to claim 10, wherein the heating element comprises a resistive heating element.

15. A system, comprising:
a reaction chamber comprising an interior space defined by:
a sidewall comprising an interior-facing surface that forms a circular shape having a first circumference;
a bottom panel coupled to the sidewall; and
a showerhead arranged opposite the bottom panel and coupled to the sidewall;
a spacer plate extending from the interior-facing surface of the sidewall into the interior space, wherein the spacer plate extends along the entire first circumference of the interior-facing surface of the sidewall;
a heating element embedded within the spacer plate;
a flow control ring positioned in direct contact with the spacer plate, wherein the flow control ring extends from an outer edge of the spacer plate into the interior space and has a second circumference;
a susceptor disposed in the interior space and adjacent to the flow control ring, the susceptor comprising a top surface; and
a cap disposed on and entirely covering the top surface of the susceptor, wherein the cap is adjacent to and spaced apart from the flow control ring.

16. The system according to claim 15, wherein the heating element is a single element that extends along the entire first circumference.

17. The system according to claim 15, wherein the heating element comprises a plurality of heating elements, wherein the heating elements are spaced equidistant from each other.

18. The system according to claim 17, wherein each heating element is configured to be independently controlled relative to the other heating elements.

19. The system according to claim 15, wherein the second circumference of the flow control ring is less than the first circumference of the sidewall.

20. The system according to claim 15, wherein the heating element comprises a resistive heating element.
